(19) United States
(12) Patent Application Publication
(10) Pub. No.: US 2004/0263218 A1
(43) Pub. Date: Dec. 30, 2004

(54) Speed enhanced damping output circuit

(76) Inventor: Eugene B. Hinterscher, McKinney, TX (US)

Correspondence Address: TEXAS INSTRUMENTS INCORPORATED, P O BOX 655474, M/S 3999, DALLAS, TX, 75265

(21) Appl. No.: 10/602,175

(22) Filed: Jun. 24, 2003

(51) Int. Cl. H03B 1/00

(52) U.S. Cl. 327/112

(57) ABSTRACT

An output circuit having undershoot/overshoot reduction, and improved propagation delay. A damping control circuit branch is provided, including a resistor and a diode connected in parallel between a first node and a second node, the second node being coupled to an output node. An output transistor, having a gate, is coupled by its source and drain between a power supply and the second node. A predriver circuit is adapted to receive an input signal and provide a voltage at the gate.

### TECHNICAL FIELD OF THE INVENTION

This invention relates to output circuits, and more particularly relates to output circuits designed to reduce undershoot and overshoot of the output signal.

### BACKGROUND OF THE INVENTION

Output circuits are used widely in the semiconductor industry. Their general purpose is to take a signal to be provided as an output from one circuit and provide it as an input to another circuit. In the process, the signal is typically buffered and amplified so that the signal is delivered with minimum delay and with sufficient amplitude to drive the receiving circuit.

One problem with output circuits, especially when designed for minimum latency (delay), is that they tend to suffer from undershoot and overshoot. That is, as the signal is driven from low to high, it tends to go over (overshoot) the target high voltage before settling to the target voltage, while, conversely, as the signal is driven from high to low, it tends to go under (undershoot) the target low voltage before settling to the target voltage.

A common prior art approach to minimizing undershoot and overshoot is to provide a damping resistor in the output circuit. While the damping resistor does improve the undershoot/overshoot problem, and also aides in increasing the impedance of the output driver, the damping effect results in a decrease in output drive strength and it increases the propagation delay in delivering the signal from one circuit to the next.

An improvement over simply providing a damping resistor in the output circuit is disclosed in U.S. Pat. No. 6,137,322, which is entitled “Dynamic Output Circuit” and which is commonly assigned. In this approach, an additional transistor is coupled in parallel with a high side output transistor, and an additional transistor is also coupled in parallel with a low side transistor. In both the high side and low side outputs, between the respective high side and low side output transistors and their associated additional parallel-coupled transistor is placed a transmission gate that is controlled by feedback from the output node. This solution alleviates the problems of overshoots and undershoots, while providing fast propagation delays. However, it requires a number of additional components to implement the feedback circuitry.

Another approach to the undershoot/overshoot problem is disclosed in U.S. Pat. No. 6,300,815, which is entitled “Voltage Reference Overshoot Protection Circuit” and which is commonly assigned. In this approach, a voltage reference overshoot protection circuit senses unwanted ringing voltage levels in a driven device, such as a backplane, and controls the gate voltage to a voltage level control transistor such that a ringing output signal produced by an associated output driver is reduced in response to a control signal dependent on the ringing voltage level. This also requires a number of additional components, to implement the voltage reference overshoot protection circuit. Also, this approach is a clamping type solution, rather than a damping type solution.

### SUMMARY OF THE INVENTION

The present invention provides an improved output circuit that provides the desired damping effect, while maintaining a minimal propagation delay. In accordance with the present invention there is provided an output circuit having undershoot/overshoot reduction, and improved propagation delay. A damping control circuit branch is provided, including a resistor and a diode connected in parallel between a first node and a second node, the second node being coupled to an output node. An output transistor, having a gate, is coupled by its source and drain between a power supply and the second node. A predriver circuit is adapted to receive an input signal and provide a voltage at the gate.

These and other features of the invention will be apparent to those skilled in the art from the following detailed description of the invention, taken together with the accompanying drawings.

### BRIEF DESCRIPTION OF THE DRAWINGS

FIG. 1 is a circuit diagram of a preferred embodiment of the present invention.

FIG. 2 is a graph showing output signal level over time, illustrating improved propagation delay achievable with the embodiment of FIG. 1.

### DETAILED DESCRIPTION OF THE PREFERRED EMBODIMENT

The numerous innovative teachings of the present invention will be described with particular reference to the presently preferred exemplary embodiments. However, it should be understood that this class of embodiments provides only a few examples of the many advantageous uses and innovative teachings herein. In general, statements made in the specification of the present application do not necessarily delimit the invention, as set forth in different aspects in the various claims appended hereto. Moreover, some statements may apply to some inventive aspects, but not to others.

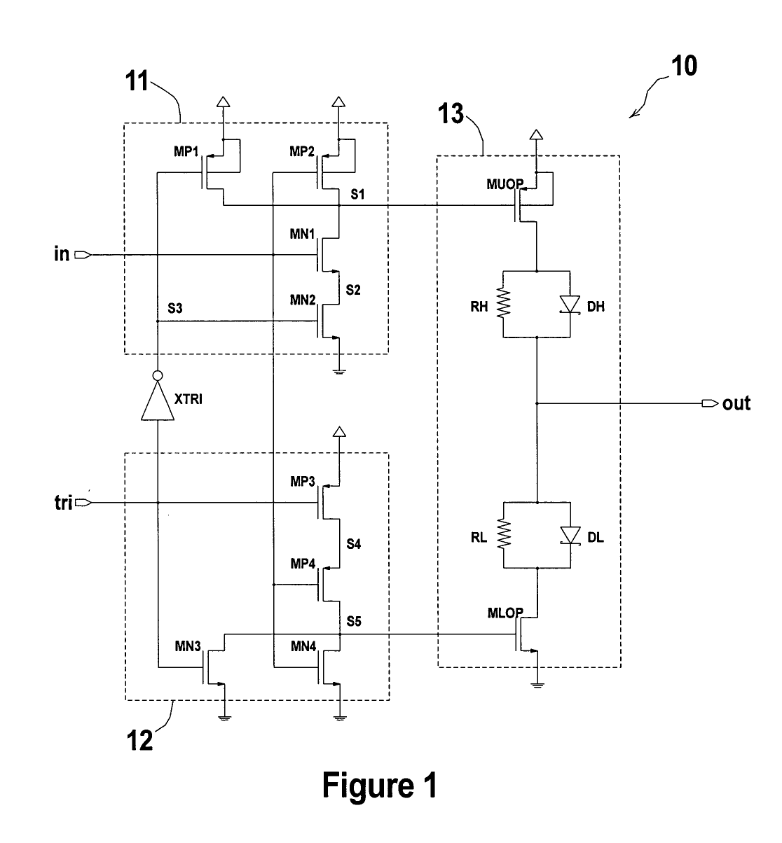

FIG. 1 is a circuit diagram of a preferred embodiment output circuit 10 of the present invention. The circuit 10 has three parts, an upper predriver 11, a lower predriver 12 and a speed-enhanced damping circuit 13. The circuit uses p-type metal oxide semiconductor (PMOS) and n-type metal oxide semiconductor (NMOS) transistors. In general, diodes are used to substantially short out a damping resistor during the initial phase of a transition. The circuit 10 provides low impedance, i.e., high dynamic current, through the AC threshold of the device being driven by circuit 10, e.g., Vcc/2. Once the initial phase of the transition is complete, and the transition has overcome the voltage drop of the diode, the diode discontinues shorting out the damping resistor and restores the damping effect (increasing the impedance) to the output driver during the critical phase of the transition. This solution provides a decrease in propagation delay while preserving the damping resistor effect. In fact, the undershoot/overshoot benefit is comparable to that of a circuit employing only a damping resistor. It also reduces skew rates over process, temperature range, and Vcc.

In circuit 10, an input signal is provided at node in to the gate of PMOS transistors MP2 and MP4 and to the gate of NMOS transistors MN1 and MN4. The source of transistor MP2 is connected to its backgate and to power supply at voltage Vcc, while its drain is connected at node S1 to the drain of transistor MN1. The source of transistor MN1 is connected at node S2 to the drain of NMOS transistor MN2, the source of which is connected to ground. A tristate enable signal is provided at a tristate input node tri to the gate of PMOS transistor MP3, to the gate of NMOS transistor MN3 and to the input of an inverter XTRI. The source of transistor MP3 is connected to Vcc, while its drain is connected at node S4 to the source of transistor MP4. The drain of transistor MP4 is connected at node S5 to the drain of transistor MN4, while the source of transistor MN4 is connected to ground. The output of inverter XTRI is connected at node S3 to the gate of PMOS transistor MP1 and to the gate of transistor MN2. The source of transistor MP1 is connected to its backgate and to Vcc, while its drain is connected to node S1. Node S1 is connected to the gate of a PMOS high side output transistor MUOP, while node S5 is connected to the gate of an NMOS low side output transistor MLOP. The source of transistor MUOP is connected to its backgate and to Vcc, while its drain is connected to one node of a branch comprising parallel connected resistor RH and diode DH, with the anode of diode DH being connected to the drain of transistor MUOP, and the cathode of diode DH being connected to the other node of the branch, which node is also the output node out of the circuit. The source of transistor MLOP is connected to ground, while its drain is connected to one node of a branch comprising parallel connected resistor RL and diode DL, with the cathode of diode DL being connected to the drain of transistor MLOP, and the cathode of diode DL being connected to the other node of the branch, which node is also the output node out of the circuit.

The output circuit 10 operates in two modes, normal mode and tri-state mode. In normal mode, the signal at node tri is low, thus driving the gate of transistor MN3 low, turning it off, and also driving the gate of transistor MP3 low, thus turning it on, and through inverter XTRI, driving the gate of transistor MP1 (node S3) high and turning it off. Thus, transistors MN3 and MP1 do not operate during normal mode.

When input signal at node in is driven high, the gates of transistors MP2 and MP4, and of transistors MN1 and MN4, are driven high. Thus, transistors MP2 and MP4 are turned off. Conversely, transistors MN1 and MN4 are turned on. This pulls nodes S1 and S5 low. This, in turn, turns transistor MUOP on, while turning transistor MLOP off. Thus, the output at node out is pulled high through the branch comprising parallel connected resistor RH and diode DH. In the initial phase of the transition of the output signal from low to high, diode DH conducts and provides a very low impedance path, effectively shorting out resistor RH. However, once the initial phase of the transition is complete, and the voltage drop across the diode no longer exceeds its threshold, the diode turns off and discontinues shorting out the damping resistor, thus restoring the damping effect of resistor RH. This increases the impedance of the output driver during the critical phase of the transition.

Again in normal mode, when input signal at node in is driven low, the gates of transistors MP2 and MP4, and of transistors MN1 and MN4, are driven low. Thus, transistors MP2 and MP4 are turned on. Conversely, transistors MN1 and MN4 are turned off. This pulls nodes S1 and S5 high. This, in turn, turns transistor MUOP off, while turning transistor MLOP on. Thus, the output out is pulled low through the branch comprising parallel connected resistor RL and diode DL. In the initial phase of the transition of the output signal from low to high, diode DL conducts and provides a very low impedance path, effectively shorting out resistor RL. However, once the initial phase of the transition is complete, and the voltage drop across the diode no longer exceeds its threshold, the diode turns off and discontinues shorting out the damping resistor, thus restoring the damping effect of resistor RH. This increases the impedance of the output driver during the critical phase of the transition.

During tri-state mode, the signal at node tri is high, thus driving the gate of transistor MN3 high, turning it on, and also driving the gate of transistor MP3 high, thus turning it off, and through inverter XTRI, driving the gate of transistor MP1 (node S3) low and turning it on. With transistor MP1 on, node S1 is pulled high, thus turning off transistor MUOP. With transistor MN3 on, node S5 is pulled low, thus turning off transistor MLOP. With transistors MUOP and MLOP off, the output is in tri-state.

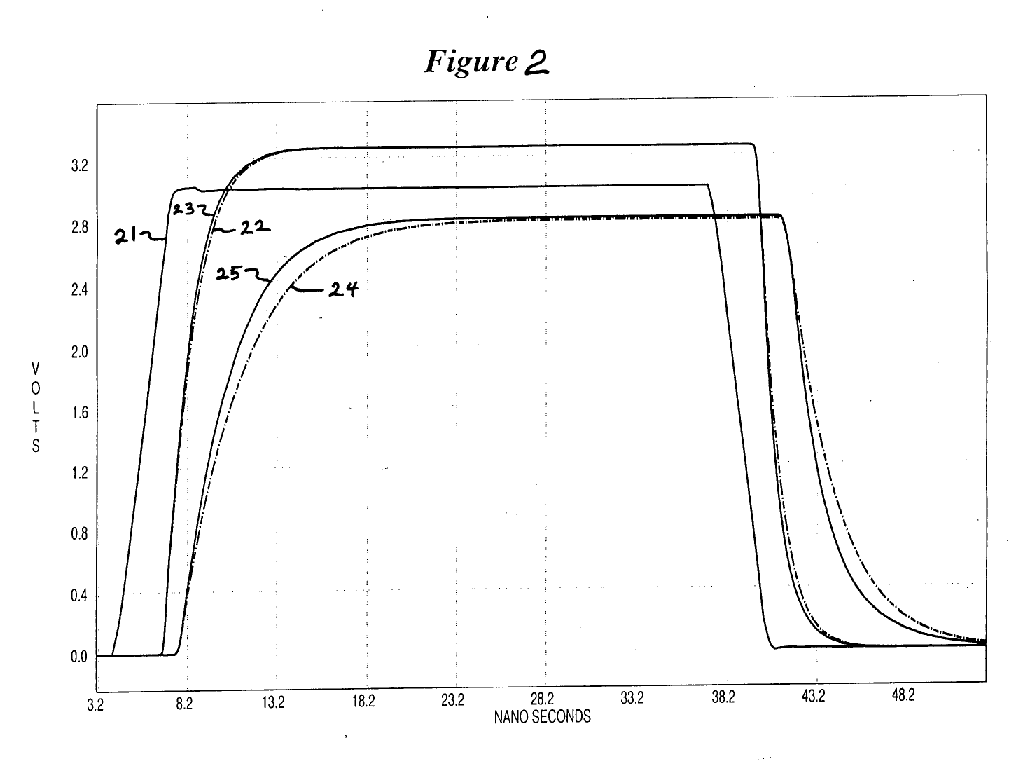

FIG. 2 is a graph of signal level versus time, and illustrates the damping effect of the circuit of FIG. 1, compared with a typical prior art circuit employing only damping resistors. Curve 21 is the input signal, while curve 22 is the output signal of a circuit employing only a damping resistor and curve 23 is the output signal of the circuit of FIG. 1, both for circuits fabricated in a strong process, with a maximum Vcc. Curve 24 is the output signal of a circuit employing only a damping resistor and curve 25 is the output signal of the circuit of FIG. 1, both for circuits fabricated in a weak process, with a minimum Vcc.

Although the present invention and its advantages have been described in detail, it should be understood that various changes, substitutions and alterations can be made herein without departing from the spirit and scope of the invention as defined by the appended claims. For example, while the preferred embodiment shown in FIG. 1 includes tristate circuitry, the invention may be implemented in output circuits not employing tristate circuitry. By way of another example, while the preferred embodiment shown in FIG. 1 includes pull-up and pull-down circuitry, in the form of upper predriver and transistor MUOP and lower predriver and transistor MLOP, the present invention may be implemented in output circuits employing only pull-up circuitry, or only pull-down circuitry.

1.-2. (cancelled)

3. An output circuit, comprising:
an upper damping control circuit branch, comprising a first resistor and a first diode connected in parallel between a first node and a second node, the second node being coupled to an output node;
a lower damping control circuit branch, comprising a second resistor and a second diode connected in parallel between a third node and the second node;
an upper output transistor coupled by its source and drain between a power supply and the first node, and having a gate;
a lower output transistor coupled by its source and drain between ground and the third node, and having a gate;
an upper predriver circuit adapted to receive an input signal and provide a voltage at the gate of the upper output transistor; and
a lower predriver circuit adapted to receive the input signal and provide another voltage at the gate of the lower output transistor.

4. An output circuit according to claim 3, further comprising a tristate circuit adapted to cause the output node to be in a tristate condition in response to a tristate enable input signal.
